(19) United States
(12) Patent Application Publication
(10) Pub. No.: US 2003/0189896 A1
(43) Pub. Date: Oct. 9, 2003

(54) Two-stage reconnect system and method

(75) Inventors: Cuong Tu Dang, Ottawa (CA); Udo Mircea Neustadter, Carp (CA); Walter Joseph Carpini, Stittsville (CA); John William Spicer, Greely (CA)

Correspondence Address: TROPIC NETWORKS INC., DR. VICTORIA DONNELLY, 135 MICHAEL COWPLAND DRIVE, KANATA, ON, K2M 2E9, CA

(73) Assignee: AR Card

(21) Appl. No.: 10/117,992

(22) Filed: Apr. 9, 2002

(51) Int. Cl. G01R 31/08; G06F 11/00

(52) U.S. Cl. 370/217; 370/395.32

(57) ABSTRACT

Methods and systems for re-routing a connection through an explicitly routed network. The methods involve initially re-routing the connection to a reduced constraint connection through the network; establishing a fully constrained path through the network; subsequently re-routing the connection to the fully constrained connection through the network.

### FIELD OF THE INVENTION

The invention relates to systems and methods for performing restoration of an explicitly routed connection after a failure has occurred.

### BACKGROUND OF THE INVENTION

In an explicitly routed network, a connection is routed over a path through the network from a source to a destination, and is subject to service disruption should some resource used by the connection fail. Typically, each connection has a connection profile which defines a set of constraints for the connection. These constraints might for example include bandwidth, maximum number of hops, delay, jitter, protection levels, shared risk groups, hop exclusions, pre-emptable traffic, layer 1 optical link protection, path exclusions. Sometimes this connection profile is formalized in the form of a contract between the service provider and the customer, sometimes referred to as a SLA (service level agreement) which details penalties which will be incurred to the service provider for service disruptions, and for failure to meet other stipulated constraints.

When a service disruption occurs, for example due to a failure of a link used on the path, it is desirable to re-route the connection as quickly as possible to another path through the network. It can take a significant amount of time to re-establish a connection which satisfies all of the constraints set out in the SLA. This is particularly the case when many connections use a given path or a given resource all of which must be re-routed at once when a failure occurs. Typically, only a very few connections can be re-routed with their full constraints within a short time frame, while other connections may not have their connectivity restored for several minutes.

Referring now to FIG. 1, shown is an example of an explicitly routed network. The network consists of a number of network nodes A,B,C,D,E,F,G, and a number of links AB,AD,AF,BC,BE,DC,FG,GE with each link interconnecting a respective pair of nodes. An example of a connection 14 between two terminals 10,12 uses network resources consisting of nodes A,B and C, and links AB and BC. A typical network would support a large number of such connections. If 1000 connections use the AB link, then when link AB fails, each connection of the 1000 connections must be re-established by re-routing it through the network. The current method of dealing with this type of failure is to individually re-compute in sequence a connection for each of the connections which have been disrupted. This is very time consuming for large numbers of connections in a large network. While this is going on, there is a large down time, particularly for the later re-routed connections. Large down times may cause SLA violations.

### SUMMARY OF THE INVENTION

One broad aspect of the invention provides a method of re-routing a connection through an explicitly routed network. The method involves initially re-routing the connection to a reduced constraint connection through the network; establishing a fully constrained path through the network; subsequently re-routing the connection to the fully constrained connection through the network.

In some embodiments, the method further involves establishing said reduced constraint connection through the network. In some embodiments, this is done after occurrence of a failure.

In some embodiments, establishing said reduced constraint connection through the network is done by pre-configuring the reduced constraint connection through the network prior to a failure.

Another broad aspect of the invention provides a method of re-routing one or more of a plurality of connections through an explicitly routed network, the plurality of connections sharing a common head node. The method involves categorizing each of said plurality of connections to be either a high priority connection or a low priority connection; for each high priority connection, pre-configuring a corresponding alternate connection through the network; upon a failure of a resource in the network: a) re-routing each high priority connection which uses the resource to use its corresponding alternate connection; b) initially re-routing each low priority connection which uses the resource to at least one reduced constraint connection through the network; c) for each low priority connection which has been re-routed to a reduced constraint connection, establishing a respective fully constrained connection through the network, or re-configuring the reduced constraint connection to be a respective fully constrained connection; d) subsequently re-routing each low priority connection which has been re-routed to the respective fully constrained connection through the network.

In some embodiments, the method further involves establishing said at least one reduced constraint connection through the network.

In some embodiments, wherein establishing said at least one reduced constraint connection through the network is done by pre-configuring the at least one reduced constraint connection through the network.

In some embodiments, establishing said at least one reduced constraint connection through the network comprises establishing a respective reduced constraint connection for each low priority connection.

In some embodiments, establishing said at least one reduced constraint connection through the network comprises establishing a respective reduced constraint connection for each of one or more sets of low priority connections.

In some embodiments, the method further involves maintaining for each high priority connection an identifier of a regular connection currently being used and an identifier of the corresponding alternate connection; and maintaining for each low priority connection an identifier of a regular connection currently being used, and an identifier of one of said at least one reduced constraint connection through the network to be used in the event of a failure of a resource on the regular connection.

In some embodiments, the method further involves maintaining information which identifies for each of a plurality of resources in the network, one or more connections which make use of the resource; whereby upon failure of one of the plurality of resources, the connections which make use of the resource can be quickly identified.

In some embodiments, the method is applied to at least one connection which is an aggregate of a plurality of connections.

In some embodiments, the method further involves tracking failures of resources used in the pre-configured alternate connections, and recalculating each pre-configured connection which uses a resource which has failed.

In some embodiments, the method further involves defining a plurality of reconnect domains within the network; and applying the method within each reconnect domain of the network.

In some embodiments, the method further involves re-routing connections in order of priority.

In some embodiments, whenever re-routing from a reduced constraint connection to a fully constrained connection, this is done so in a manner adapted to prevent frame mis-ordering at a receiver.

In some embodiments, the method further involves for at least one connection pre-routing a respective at least one path through the network; after a failure of a resource used by one of said at least one connection, setting up a new connection using a respective one of said at least one path, and re-routing the one of said at least one connection to the new connection.

Another broad aspect of the invention provides a network node having a plurality of user cards allowing connection of external devices to the network node; a plurality of network cards allowing connection of the network node to other parts of a network of which the network node forms a part; a connection manager adapted to manage plurality of connections initiated at the network node through the network of which the network node forms a part; a multi-constraint router adapted to calculate routes through the network of which the network node forms a part; the network node being adapted to maintain resource usage information identifying for each of a plurality of resources in the network which of said plurality connections use the resource; upon a failure of a resource in the network, the network node being adapted to: a) re-route each connection which uses the resource to a corresponding reduced constraint connection; b) for each connection which has been re-routed, establish a respective fully constrained connection through the network; c) subsequently re-route each connection which has been re-routed to the respective fully constrained connection through the network.

Another broad aspect of the invention provides a network node having a plurality of user cards allowing connection of external devices to the network node; a plurality of network cards allowing connection of the network node to other parts of a network of which the network node forms a part; a connection manager adapted to manage a plurality of connections initiated at the network node through the network of which the network node forms a part; a multi-constraint router adapted to calculate routes through the network of which the network node forms a part; the network node being adapted to maintain resource usage information identifying for each of a plurality of resources in the network which of said plurality connections use the resource; the network node being adapted to maintain priority information for each of said plurality of connections enabling each connection to be categorized to be either a high priority connection or a low priority connection; for each high priority connection, the network node being adapted to pre-configuring a corresponding alternate connection through the network; upon a failure of a resource in the network, the network node being adapted to: a) re-route each high priority connection which uses the resource to use its corresponding alternate connection; b) initially re-route any low priority connections which uses the resource to at least one reduced constraint connection through the network; c) for each low priority connection which has been re-routed, establish a respective fully constrained connection through the network; d) subsequently re-route each low priority connection which has been re-routed to the respective fully constrained path through the network.

### BRIEF DESCRIPTION OF THE DRAWINGS

Preferred embodiments of the invention will now be described with reference to the attached drawings in which:

FIG. 1 is a schematic diagram of an example of an explicitly routed network;

FIG. 2 is a flowchart of a two-stage reconnect method provided by an embodiment of the invention;

FIG. 3 is a flowchart of another two-stage reconnect method provided by another embodiment of the invention;

FIG. 4 is a flowchart of a another two-stage reconnect method provided by another embodiment of the invention;

FIG. 5 is a flowchart of another two-stage reconnect method provided by another embodiment of the invention;

FIG. 6 is a block diagram of a network node adapted to implement at least one of the methods of FIGS. 2, 3, 4 and 5; and

FIG. 7 is a schematic diagram of a network within which the two-stage reconnect methods of FIGS. 2, 3, 4 or 5 are applied on a per protection domain basis.

### DESRIPTION OF THE PREFERRED EMBODIMENTS

Embodiments of the invention provide new methods of re-routing a connection. These may be employed when there is a failure of a resource used by the connection, but this need not necessarily be the case. More generally, any time a quick re-routing from the existing connection must be achieved, the method provided by the invention may be employed. In what follows, a path is a set of resources which may be used to carry traffic between two points but which may or may not be set up and may or may not be carrying any traffic. A connection is a path which is set up to carry traffic and which may or may not actually be carrying traffic.

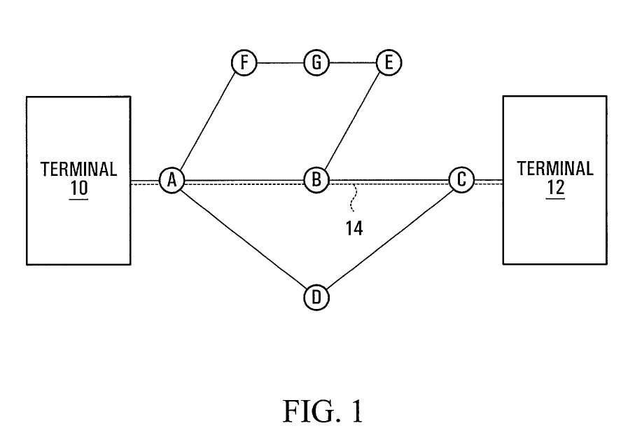

Typically, it is the head node's responsibility to deal with a failure of a resource used by a connection, the head node being the first network node involved in the connection. For the connection 14 of FIG. 1, node A is the head node. Thus, an input to any of these methods is the head node somehow becoming aware of the failure having occurred. This can be achieved using any suitable method. In a preferred embodiment, the so called “fast link state announcement” methodology is employed to quickly inform the head node of failures which have occurred on its connections. This methodology is taught in commonly assigned provisional application No. 60/290,386 incorporated by reference in its entirety and in regular application Ser. No. ______ filed Mar. 19, 2002 entitled “Packet Network Providing Fast Distribution of Node Related Information and a Method Therefor” which is also commonly assigned claims priority from the above-noted provisional. If the connection is segmented, then it is the segment head's responsibility of re-routing.

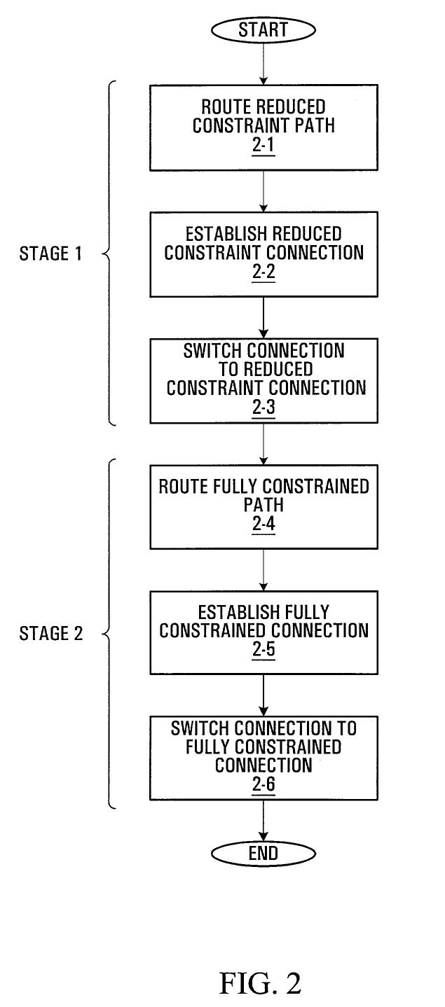

In a first embodiment of the invention, when a service disruption occurs to a connection, a two stage reconnection procedure is employed. This will be described with reference to the flowchart of FIG. 2.

The purpose of the first stage is to provide connectivity for all connections in the shortest possible time at the expense of full constraints. The first stage in the method employed for an existing connection which uses a failed resource begins with the step 2-1 of routing a new reduced constraint path followed by the step 2-2 of establishing a new “reduced constraint” connection over the paths thus identified. This reduced constraint connection does not satisfy all of the parameters set out in the SLA, and may not in fact satisfy any of the parameters except the endpoints of the connection. Preferably, the connection has as few constraints as possible, and ideally none, such that the connection can be established as quickly as possible. For example, the connection may be considered to offer “best effort” service (BE), having no guaranteed bandwidth, no maximum delay etc. Once the reduced constraint connection is established, the existing connection is switched to the reduced constraint connection in step 2-3.

After having provided connectivity with the first stage, the purpose of the second stage is to satisfy the constraints for the re-routed connections. The second stage begins with the step 2-4 of routing a fully constrained path followed by the step 2-5 of establishing the fully constrained connection using the path. The fully constrained connection may for example be one which satisfies all of the constraints specified in the SLA. Once this fully constrained connection is established, in step 2-6 the connection is switched to the fully constrained connection.

Advantageously, because the establishment of reduced constraint paths can be done very quickly, this method allows all failed connections to be re-established within some specified period of time.

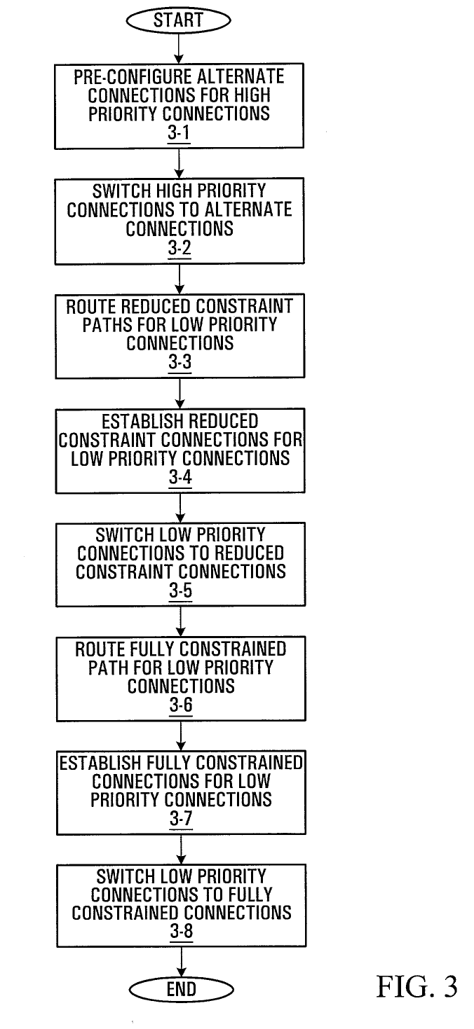

Another embodiment of the invention will now be described with reference to the flowchart of FIG. 3. In this embodiment, each head node maintains a priority for each connection starting at the head node. This priority can be any information reflective of the importance of a connection being re-routed quickly. Using this priority, connections are categorized into “high priority connections” and “low priority connections”. For each high priority connection, prior to the occurrence of a failure, a fully constrained alternate connection is pre-configured (path routed and connection established) at step 3-1. This is done at the time of the initial path setup. When a failure of a resource occurs, the high priority connections which use the resource are switched immediately to the pre-configured fully constrained alternate connections at step 3-2. Preferably, another connection is then established to take over as the alternate connection. Preferably, the pre-configured fully constrained alternate connection is maximally disjoint from the regular connection such that a failure of a resource on the regular connection is unlikely to effect the pre-configured fully constrained alternate connection.

For the remaining connections, the two-stage approach described above with reference to FIG. 2 is employed. They are first switched to reduced constraint connections (steps 3-3,3-4,3-5). Then, later when the network has stabilized, the lower priority connections will be switched to fully constrained connections if necessary to meet their SLA parameters (steps 3-6,3-7,3-8).

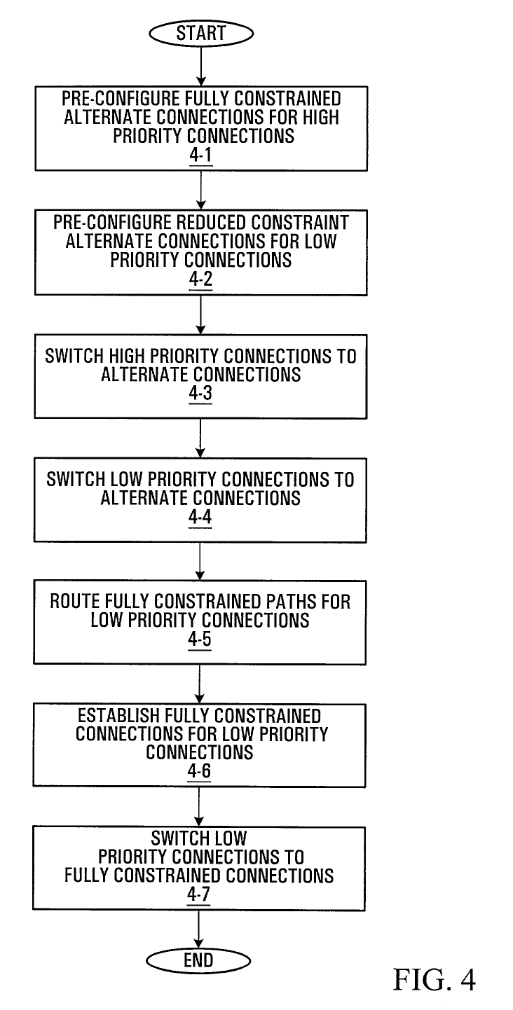

Another embodiment of the invention will now be described with reference to the flowchart of FIG. 4. In this embodiment, a fully constrained alternate connection is pre-configured for high priority connections at step 4-1, and a reduced constraint alternate connection is pre-configured (routed and established) for each low priority connection at step 4-2. In this embodiment, each pre-configured reduced constraint alternate connection does not take up any resources until it is actually carrying traffic. In this embodiment, head nodes must maintain an identification of two connections per source, destination pair, for example in a connection database.

When a failure of a resource occurs, the high priority connections which use the resource are switched immediately to the pre-configured fully constrained alternate connections at step 4-3. Preferably, the pre-configured fully constrained alternate connection is maximally disjoint from the regular connection such that a failure of a resource on the regular connection is unlikely to effect the pre-configured fully constrained alternate connection. The low priority connections are then switched to the pre-configured reduced constraint alternate connections at step 4-4. Then, once the network stabilizes, fully constrained connections are routed and established for the low priority connections at steps 4-5 and 4-6, and the low priority connections are switched to use the new connections at step 4-7.

This embodiment solves the connectivity issues by providing instant connectivity for all connections, and fully constrained connectivity for the high priority calls. It also guarantees that all of the connection constraints will be eventually satisfied. This approach satisfies the small number of high paying customers since their connections will meet their constraints during a reconnect situation.

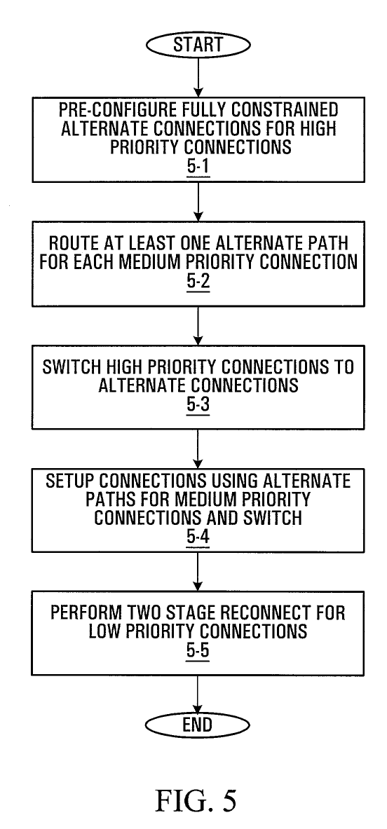

Another embodiment of the invention will be described with reference to the flowchart of FIG. 5. In this embodiment, the connections are divided into three different priorities, low, medium and high, and each priority gets different treatment. In step 5-1, a fully constrained alternate connection is pre-configured for each high priority connection. In step 5-2, at least one alternate path is routed, but not set up for each medium priority connection. The number of alternate paths to be routed per connection can be set as a system parameter. Once a failure occurs, high priority connections are re-routed to use the alternate connections in step 5-3. For the medium priority connections, one of the alternate paths is set up as a connection, and the connection is switched over to use the newly set up connection in step 5-4. Finally, for low priority connections, the previously described two-stage reconnect is performed in step 5-5.

It is to be understood that there are many methods or implementations of coordinating and keeping track of connections using these two-stage approaches and the invention is not limited to one particular method or implementation. The following example assumes a pre-configured alternate connection for each connection. In this example, each head node maintains a list of connections and the information related to each connection, including the resources used by each connection, whether it is a regular or alternate connection, and the connection ID of a corresponding alternate or regular connection, as shown in Table 1.

TABLE 1

| Connection ID | Resource IDs | Connection Type | Connection ID |
|---|---|---|---|
| C1 | AC, CD | Primary | C1′ |
| C1′ | AB, BD | Alternate | C1 |
| C2 | AC, CD | Primary | C2′ |
| C2′ | AE, ED | Alternate | C2 |

Typically, a resource failure will affect many connections, so a mechanism is needed to quickly identify all connections affected by the failure. In one embodiment, each head node maintains a list of network resources (for example nodes, links), and for each network resource a corresponding list of connections that originate from the head node and use the resource.

For example, this might take the form of a table with a row for each resource, and a corresponding list of connections using the resource. Table 2 below provides an example of this in which there is a column for a resource identifier, and a column for connection identifiers of regular connections making use of the resource. Any suitable type of resource identifier and connection identifier may be employed. Table 3 provides similar information for alternate connections.

TABLE 2

| Resource ID | Connection IDs |
|---|---|
| AC | C1, C2 |
| CD | C1, C2 |

TABLE 2

| Resource ID | Connection IDs |
|---|---|
| AB | C1 |
| AE | C2 |
| BD | C1 |
| ED | C2 |

In the example of Table 1, two regular connections are identified, namely C1 and C2, along with their corresponding alternate connections, namely C1′ and C2′. In the example of Table 2, two resources are identified, namely AC and CD, along with the Connection IDs of the regular connections using the resource. Table 3 identifies four resources, namely AB, AE, BD, and ED, along with the Connection IDs of the alternate connections using the resource. Typical tables of this sort would of course have a much larger number of entries for both resource identifiers and connection identifiers.

For the purpose of two-stage reconnect, at any instant there may be two connections, the regular connection which uses a fully constrained path through the network, and the alternate connection which uses the non-constrained path through the network. A connection is considered to be ‘Valid’ when it has been setup through the network and is capable of carrying traffic from the source node to the destination node. At all other times the connection is considered ‘Invalid’. During a two-stage reconnect, there are two possible states, ‘Active’, which always will have a ‘Valid’ connection, and ‘Restore’, which may or may not have a ‘Valid’ connection.

The Active state for a regular connection, means the connection is setup and carrying traffic. Similarly, the Active state for an alternate connection, this means the connection is setup and capable of carrying traffic.

The Restore state for a regular connection means that the process of calculating and setting up a new fully constrained connection is ongoing. Similarly, for the alternate connection, the Restore state means that the process of calculating and setting up a new alternate connection is ongoing.

While in the ‘Restore’ state, there are four possible actions:

1) Routing, which is the process of calculating a new path through the network;

2) Setup, which is the process of signaling all the nodes along the path through the network to setup the connection. The switching action is only applicable to the regular connection, and involves updating the connection's resource list with the resources of the new path;

3) Switching, which is the process of moving traffic from one connection to another connection; and

4) Waiting, which is what the alternate connection does when it is blocked waiting for an action to complete on the regular connection.

The following examples illustrate the actions and state transitions for various failure scenarios.

### EXAMPLE 1

### Resource Failure Along the Regular Connection

In the case of a resource failure along the regular connection, the connection is immediately switched to the alternate connection, and the resource list from the alternate connection is copied to the regular connection meaning that the regular connection is now identical to the alternate connection. The state of the primary and alternate connection is set to ‘Restore’ and the alternate connection ‘Valid Path’ flag is set to ‘No’. When the primary connection is in the restoration state and there is a valid connection, (i.e., switched over to the alternate connection) an attempt could be made to modify the current path (which is not guaranteed to meet full constraints) to meet the full constraints. If the path modification succeeds, the connection is meeting its constraints and a new alternate connection can be computed and setup. If the modification fails, then a new fully constrained connection will be computed and setup, followed by the creation of a new alternate connection. Tables 2 and 3 would be updated with the new resource usage information. The decision to attempt the path modification or not is directly related to the packet ordering requirements imposed on the connection, and the methods available for dealing with out-of-order packets. The state transitions and actions for this example are summarized in Table 4 below.

TABLE 4

| ID | State | Action | Valid Path |
|---|---|---|---|
| C1 | Active | — | Y |
| C1′ | Active | — | Y |
| C1 | Restore | Switching | Y |
| C1′ | Restore | Waiting | N |
| C1 | Restore | Routing | Y |
| C1′ | Restore | Waiting | N |
| C1 | Restore | Setup | Y |
| C1′ | Restore | Routing | N |
| C1 | Restore | Switching | Y |
| C1′ | Restore | Routing | N |
| C1 | Active | — | Y |
| C1′ | Restore | Setup | N |
| C1 | Active | — | Y |
| C1′ | Active | — | Y |

In table 4, when C1 is in the switching state the first time, the resources used by the alternate connection are transferred to the regular connection. Effectively, the alternate connection becomes the regular connection.

### EXAMPLE 2

### Resource Failure Along the Alternate Connection

In the case of a resource failure along the alternate connection, the alternate connection state is changed to ‘Restore’. A new alternate connection is completed and set up through the network. The corresponding entry in Table 3 would be updated according to the new resource information. The state transitions and actions for example are summarized in Table 5 below.

TABLE 5

| ID | State | Action | Valid Path |
|---|---|---|---|
| C1 | Active | — | Y |
| C1′ | Active | — | Y |
| C1 | Active | — | Y |
| C1′ | Restore | Routing | N |
| C1 | Active | — | Y |
| C1′ | Restore | Setup | N |
| C1 | Active | — | Y |
| C1′ | Active | — | Y |

### EXAMPLE 3

### Resource Failure on a Shared Link that Affects Both Regular and Alternate Connections

In the case of a resource failure affecting both the regular and alternate connections, a single stage full constraint restoration of the connection is performed. The regular connection is put into the ‘Restore’ state, and the ‘Valid Path’ flag is set to ‘No’ to trigger the creation of a new fully constrained connection. The alternate connection is put into the ‘Restore’ state to trigger the creation of a new alternate connection. Tables 2 and 3 would be updated with the new resource information as each connection enters the ‘Active’ state. Table 6 shows an example series of state transitions.

TABLE 6

| ID | State | Action | Valid Path |
|---|---|---|---|
| C1 | Active | — | Y |
| C1′ | Active | — | Y |
| C1 | Restore | Routing | N |
| C1′ | Restore | Waiting | N |
| C1 | Restore | Setup | N |
| C1′ | Restore | Routing | N |
| C1 | Restore | Setup | N |
| C1′ | Restore | Routing | N |
| C1 | Active | — | Y |
| C1′ | Restore | Setup | N |
| C1 | Active | — | Y |
| C1′ | Active | — | Y |

### EXAMPLE 3

### Second Failure after Switch to Alternate Connection, but Before a New Constrained Connection is Setup

If a second resource failure occurs that affects a connection, the action taken will depend on the states of the regular and alternate connections. If the regular connection is in the ‘Restore’ state, then the connection is already in the progress of re-computing a new fully constrained path, so no further action is required. If the regular connection is in the ‘Active’ state and the alternate connection is in the ‘Restore’ state, the regular connection will be changed to the ‘Restore’ state as well. This will trigger the creation of a new fully constrained connection, followed by the creation of a new alternate connection. Example state transitions are shown in Table 7.

In this example, it is assumed that while C1 is performing the Routing action, a second failure occurs, which affects the alternate connection. The connection is no longer passing traffic.

Typically a switching node includes line cards to which external devices are connected, network cards which connect the switching node to other nodes in a network, and control cards which manage the connections originating at the node. When a failure occurs, it is propagated to the head node through a line card or network card, for example using the fast link state announcement technique referred to above. The failure is then propagated to the other line cards on the node.

The connection state information and resource usage information might for example be maintained in a control card of head nodes. Also, a subset of the information may be maintained by each line card for connections originating the call (user cards). The information may also need to be on the network cards as well. This is useful for quick restoration and scalability.

For embodiments with pre-configured alternate connections (either fully constrained or reduced constraint) the user cards can be pre-programmed with the re-routing information and can coordinate the switch over to the alternate connection upon occurrence of a failure.

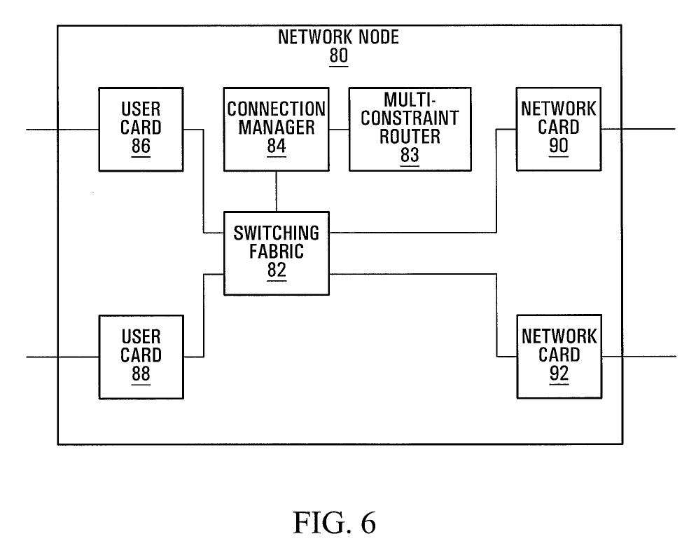

Referring now to FIG. 6, shown is a block diagram of a head node generally indicated by 80 adapted to implement one or more of the above discussed methods. The node has a switching fabric 82 controlled by a connection manager 84. Also shown is an multi-constraint router 83 capable of determining explicit routes through the network of which the node forms a part upon request from the connection manager. The node has a number of user cards (only two shown) 86,88 through which connections from external to the network are made. Similarly, the node has a number of network cards (only two shown) 90,92 through which connections within the network are made.

In one embodiment, the connection manager 84 is responsible for coordinating the various two-stage reconnect methods described above. In another embodiment, the user card 86 may initiate the initial switch over to the reduced constraint path. This would typically only be for the high priority connections. The connection manager 84 then co-ordinates the computation of the fully constrained connection and coordinates the second switch over to new connection.

For the lower priority connections, the multi-constraint router 83 may generate the new reduced constraint path upon the reconnect request from the connection manager 84, and employ an AECMP (almost equal cost multi-path) algorithm to distribute the connections. Afterwards, the connection manager 84 will attend to the connections that do not meet their SLAs and request a new path from the multi-constraint router 83. The approach here is make before break.

In another embodiment, the reduced constraint connections are also pre-provisioned in the form of a reduced constraint tunnel. This does not take up any network resources so long as traffic is sent on these connections. Preferably, multiple connections are mapped to the reduced constraint tunnel instead of having 1:1 reduced constraint paths, but 1:1 can alternatively be employed. For example, 5 maximally disjoint reduced constraint connections may be computed, and the 1000 connections which need to be re-routed are sent over these reduced constraint connections. Reduced constraint tunnels may alternately be computed at the time of failure.

In the above described embodiments, the two-stage reconnect method is employed on a per connection basis. In another embodiment, the two-stage reconnect method is employed for aggregate connections.

In another embodiment, for the pre-configured reduced constraint alternate connections, the method further involves tracking failures of resources used in the pre-configured reduced constraint alternate connections, and re-routing and establishing the alternate connections when necessary.

It is noted that the above embodiments have performed two-stage reconnect for an end-to-end connection. In another embodiment of the invention, the two-stage reconnect method is employed within reconnect domains of a network which are used as building blocks for end-to-end connections. In this case, an end-to-end connection is in effect sliced into sections, and the invention can be applied to each section as required.

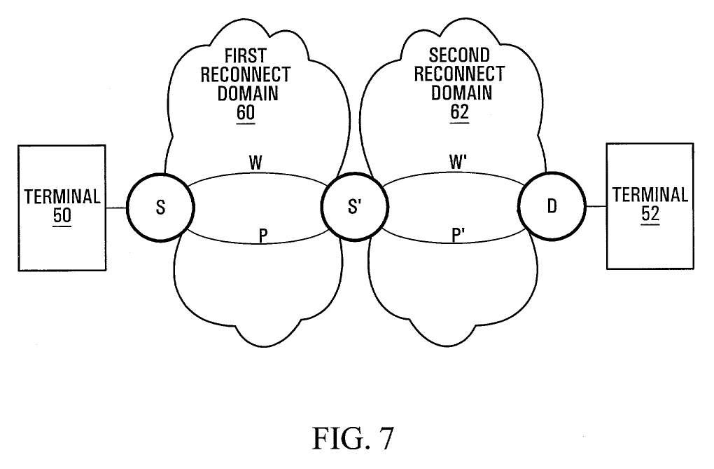

An example of this is shown in FIG. 7 which shows details of the provisioning for a connection from a first terminal 50 to a second terminal 52. The connection enters the network at a source node S. A regular connection W is established between node S and node S′ which may involve other nodes and links, not shown. A regular path W′ is also established between node S′ and a node D through which the connection exits the network to the second terminal 52. A part of the network containing regular path W is a first reconnect domain 60, and a part of the network containing regular path W′ is a second reconnect domain 62. The node S′ is effectively a head node for the second reconnect domain 62. In this embodiment, one of the two stage reconnection methods described previously is applied on a per reconnect domain basis. Faults which occur in the first reconnect domain 60 which effect the connection are handled by node head S which coordinates a two-stage reconnect process to another connection through the first reconnect domain 60 from node S to node S′. Similarly, faults which occur in the second reconnect domain 62 which effect the connection are handled by node head S′ which coordinates a two-stage reconnect process to another connection through the second reconnect domain 62 from node S′ to node D. This relies on a high reliability of node S′ since it must stay up as an end node in the first reconnect domain 60 and as a head node in the second reconnect domain 62. A network can be divided into an arbitrary number of reconnect domains.

In a preferred embodiment, the reconnection of the connections re-routed over reduced constraint connections is done in a prioritized fashion, for example from smallest to largest bandwidth, or by class of service.

In the preferred embodiments described above, the two-stage reconnect functionality is distributed in the sense that each head node is responsible locally for implementing the method. The two-stage reconnect methods are also applicable in a network with centralized control.

It is noted that some applications/devices are not set up to handle mis-ordered frames. Frame mis-ordering may in some cases occur when re-routing from the reduced constraint connection to the fully constrained connection because the performance of the fully constrained connection will likely be superior to that of the reduced constraint connection, and certain frames transmitted on the fully constrained connections may arrive at the connection end-point before the arrival of frames which were transmitted over the reduced constraint connection before those certain frames.

The above methods are well suited to connections employing TCP. It is noted that when there is an interruption within a TCP connection, it is a characteristic of TCP to perform a “slow start” (i.e. TCP will only send at very low rates from the source), and this is well suited for the above described methods. The “slow start” gives a node the ability to handle a slew of instantaneous connections. If there was no slow start, a fail over of a lot of connections to a certain path may cause connection problems.

Numerous modifications and variations of the present invention are possible in light of the above teachings. It is therefore to be understood that within the scope of the appended claims, the invention may be practised otherwise than as specifically described herein.

1. A method of re-routing a connection through an explicitly routed network comprising:
initially re-routing the connection to a reduced constraint connection through the network;
establishing a fully constrained path through the network;
subsequently re-routing the connection to the fully constrained connection through the network.

2. A method according to claim 1 further comprising:
establishing said reduced constraint connection through the network.

3. A method according to claim 2 wherein establishing said reduced constraint connection through the network is done after occurrence of a failure.

4. A method according to claim 2 wherein establishing said reduced constraint connection through the network is done by pre-configuring the reduced constraint connection through the network prior to a failure.

5. A method of re-routing one or more of a plurality of connections through an explicitly routed network, the plurality of connections sharing a common head node, the method comprising:
categorizing each of said plurality of connections to be either a high priority connection or a low priority connection;
for each high priority connection, pre-configuring a corresponding alternate connection through the network;
upon a failure of a resource in the network:
a) re-routing each high priority connection which uses the resource to use its corresponding alternate connection;
b) initially re-routing each low priority connection which uses the resource to at least one reduced constraint connection through the network;
c) for each low priority connection which has been re-routed to a reduced constraint connection, establishing a respective fully constrained connection through the network, or re-configuring the reduced constraint connection to be a respective fully constrained connection;
d) subsequently re-routing each low priority connection which has been re-routed to the respective fully constrained connection through the network.

6. A method according to claim 5 further comprising:
establishing said at least one reduced constraint connection through the network.

7. A method according to claim 6 wherein establishing said at least one reduced constraint connection through the network is done after occurrence of a failure.

8. A method according to claim 6 wherein establishing said at least one reduced constraint connection through the network is done by pre-configuring the at least one reduced constraint connection through the network.

9. A method according to claim 6 wherein establishing said at least one reduced constraint connection through the network comprises establishing a respective reduced constraint connection for each low priority connection.

10. A method according to claim 6 establishing said at least one reduced constraint connection through the network comprises establishing a respective reduced constraint connection for each of one or more sets of low priority connections.

11. A method according to claim 8 further comprising:
maintaining for each high priority connection an identifier of a regular connection currently being used and an identifier of the corresponding alternate connection; and
maintaining for each low priority connection an identifier of a regular connection currently being used, and an identifier of one of said at least one reduced constraint connection through the network to be used in the event of a failure of a resource on the regular connection.

12. A method according to claim 5 further comprising:
maintaining information which identifies for each of a plurality of resources in the network, one or more connections which make use of the resource; whereby upon failure of one of the plurality of resources, the connections which make use of the resource can be quickly identified.

13. A method according to claim 5 applied to at least one connection which is an aggregate of a plurality of connections.

14. A method according to claim 5 further comprising:
tracking failures of resources used in the pre-configured alternate connections, and recalculating each pre-configured connection which uses a resource which has failed.

15. A method according to claim 5 further comprising:
defining a plurality of reconnect domains within the network; and
applying the method of claim 5 within each reconnect domain of the network.

16. A method according to claim 5 further comprising:
re-routing connections in order of priority.

17. A method according to claim 5 wherein:
whenever re-routing from a reduced constraint connection to a fully constrained connection, doing so in a manner adapted to prevent frame mis-ordering at a receiver.

18. A method according to claim 1 further comprising:
for at least one connection pre-routing a respective at least one path through the network;
after a failure of a resource used by one of said at least one connection, setting up a new connection using a respective one of said at least one path, and re-routing the one of said at least one connection to the new connection.

19. A network node comprising:
a plurality of user cards allowing connection of external devices to the network node;
a plurality of network cards allowing connection of the network node to other parts of a network of which the network node forms a part;
a connection manager adapted to manage plurality of connections initiated at the network node through the network of which the network node forms a part;
a multi-constraint router adapted to calculate routes through the network of which the network node forms a part;
the network node being adapted to maintain resource usage information identifying for each of a plurality of resources in the network which of said plurality connections use the resource;
upon a failure of a resource in the network, the network node being adapted to:
a) re-route each connection which uses the resource to a corresponding reduced constraint connection;
b) for each connection which has been re-routed, establish a respective fully constrained connection through the network;
c) subsequently re-route each connection which has been re-routed to the respective fully constrained connection through the network.

20. A network node comprising:
a plurality of user cards allowing connection of external devices to the network node;
a plurality of network cards allowing connection of the network node to other parts of a network of which the network node forms a part;
a connection manager adapted to manage a plurality of connections initiated at the network node through the network of which the network node forms a part;
a multi-constraint router adapted to calculate routes through the network of which the network node forms a part;
the network node being adapted to maintain resource usage information identifying for each of a plurality of resources in the network which of said plurality connections use the resource;
the network node being adapted to maintain priority information for each of said plurality of connections enabling each connection to be categorized to be either a high priority connection or a low priority connection;
for each high priority connection, the network node being adapted to pre-configuring a corresponding alternate connection through the network;
upon a failure of a resource in the network, the network node being adapted to:
a) re-route each high priority connection which uses the resource to use its corresponding alternate connection;
b) initially re-route any low priority connections which uses the resource to at least one reduced constraint connection through the network;
c) for each low priority connection which has been re-routed, establish a respective fully constrained connection through the network;
d) subsequently re-route each low priority connection which has been re-routed to the respective fully constrained path through the network.
